(19) United States
(12) Patent Application Publication
(10) Pub. No.: US 2016/0108311 A1
(43) Pub. Date: Apr. 21, 2016

(54) PHOSPHORS

(71) Applicant: MERCK PATENT GMBH, Darmstadt (DE)

(72) Inventors: Holger WINKLER, Darmstadt (DE); Ralf PETRY, Griesheim (DE); Tim VOSGROENE, Ober-Ramstadt (DE); Peter BARNEKOW, Hockenheim (DE); Thomas JUESTEL, Witten (DE); Claudia SUESSEMILCH, Muenster (DE)

(73) Assignee: MERCK PATENT GMBH, Darmstadt (DE)

(21) Appl. No.: 14/888,515

(22) PCT Filed: Apr. 7, 2014
(86) PCT No.: PCT/EP2014/000923

§ 371 Date: Nov. 2, 2015

(30) Foreign Application Priority Data
May 2, 2013 (DE) 13002368.2

(51) Int. Cl. C09K 11/77; H01L 33/50

(52) U.S. Cl. CPC C09K 11/7774; H01L 33/502

(57) ABSTRACT

The present invention relates to garnet phosphors, to a process for the preparation thereof and to the use thereof as conversion phosphors. The present invention also relates to an emission-converting material comprising at least the conversion phosphor according to the invention, and to the use thereof in light sources, in particular pc-LEDs (phosphor converted light emitting devices). The present invention furthermore relates to light sources, in particular pc-LEDs, and to lighting units which comprise a primary light source and the emission-converting material according to the invention.

The present invention relates to garnet phosphors, to a process for the preparation thereof and to the use thereof as conversion phosphors. The present invention also relates to an emission-converting material comprising the conversion phosphor according to the invention and to the use thereof in light sources, in particular pc-LEDs (phosphor converted light emitting devices). The present invention furthermore relates to light sources, in particular pc-LEDs, and to lighting units which comprise a primary light source and the emission-converting material according to the invention.

For more than 100 years, inorganic phosphors have been developed in order to adapt the spectra of emissive display screens, X-ray amplifiers and radiation or light sources in such a way that they meet the requirements of the respective area of application in as optimal a manner as possible and at the same time consume as little energy as possible. The type of excitation, i.e. the nature of the primary radiation source and the requisite emission spectrum, is of crucial importance here for the choice of host lattice and the activators.

In particular for fluorescent light sources for general lighting, i.e. low-pressure discharge lamps and light-emitting diodes, novel phosphors are constantly being developed in order further to increase the energy efficiency, colour reproduction and stability.

There are in principle three different approaches to obtaining white-emitting inorganic LEDs (light emitting diodes) by additive colour mixing:
(1) RGB LEDs (red+green+blue LEDs), in which white light is generated by mixing the light from three different light-emitting diodes which emit in the red, green and blue spectral region.
(2) UV LED+RGB phosphor systems, in which a semiconductor which emits in the UV region (primary light source) emits the light to the environment, in which three different phosphors (conversion phosphors) are stimulated to emit in the red, green and blue spectral region. Alternatively, it is possible to use two different phosphors which emit yellow or orange and blue.
(3) Complementary systems, in which an emitting semiconductor (primary light source) emits, for example, blue light, which stimulates one or more phosphors (conversion phosphors) to emit light, for example in the yellow region. By mixing the blue and yellow light, white light is then produced. Alternatively, it is possible to use two or more phosphors which emit, for example, green or yellow and orange or red light.

Binary complementary systems have the advantage that they are capable of producing white light with only one primary light source and—in the simplest case—with only one conversion phosphor. The best-known of these systems consists of an indium aluminium gallium nitride chip as primary light source, which emits light in the blue spectral region, and a cerium-doped yttrium aluminium garnet (YAG:Ce) as conversion phosphor, which is excited in the blue region and emits light in the yellow spectral region. However, improvements in the colour rendering index and the stability of the colour temperature are desirable. Further garnet phosphors of the general formula (Y,Gd,Lu,Tb)₃(Al,Ga,Sc)₅O₁₂:Ce are also known for this use. Garnet phosphors are of particular interest owing to the high stability to air and moisture.

On use of a blue-emitting semiconductor as primary light source, binary complementary systems thus require a yellow conversion phosphor in order to reproduce white light. Alternatively, it is possible to use green- and red-emitting conversion phosphors. If, as an alternative, the primary light source used is a semiconductor which emits in the violet spectral region or in the near-UV spectrum, either an RGB phosphor mixture or a dichromatic mixture of two complementary light-emitting conversion phosphors must be used in order to obtain white light. On use of a system having a primary light source in the violet or UV region and two complementary conversion phosphors, light-emitting diodes having a particularly high lumen equivalent can be provided. A further advantage of a dichromatic phosphor mixture is the lower spectral interaction and the associated higher package gain.

In particular, inorganic fluorescent powders which can be excited in the blue and/or UV region of the spectrum are therefore gaining ever-greater importance today as conversion phosphors for light sources, in particular for pc-LEDs.

An essential disadvantage of the use of a primary light source having a Ce³⁺-doped garnet phosphor with broadband emission or an LED having a dichromatic spectrum (blue+yellow-orange) is its dependence of the colour reproduction on the colour temperature. Low colour temperatures (T_{c}<5000 K) can, in addition, not be achieved with sufficiently high colour reproduction (CRI>80) due to the absence of deep-red spectral components.

There is a constant demand for novel conversion phosphors which can be excited in the blue or UV region and emit light in the visible region, in particular in the green spectral region.

It is thus an object of the present invention to provide compounds which have a higher proportion of the emission in the red spectral region compared with simple cerium-doped garnet phosphors or which have an emission spectrum with an emission maximum which is shifted compared with simple cerium-doped garnet phosphors. This provides the person skilled in the art with a greater selection of suitable materials for the production of white-emitting devices.

Surprisingly, it has been found that suitable garnet phosphors having a high photoluminescence quantum yield are obtained if Mn²⁺ is employed as co-doping in addition to the cerium doping and the incorporation of divalent manganese into the lattice sites of trivalent aluminium is compensated for by the incorporation of halide ions into the lattice sites of oxygen. These phosphors have a red-shifted emission band compared with purely Ce³⁺-doped garnets.

JP 2009/079094 discloses garnet phosphors which have been co-doped with Mn²⁺ in addition to Ce³⁺. The charge compensation here takes place via the simultaneous incorporation of silicon instead of aluminium. Garnet phosphors having Mn²⁺ co-doping which simultaneously contain halogen are not described.

The present invention therefore relates to a compound of the following formula (1),

M₃₋ₓCeₓ(Al_{5-y-z-w}Ga_{z}Sc_{w})Mn_{y}O_{12-y}Hal_{y} (1)

where the following applies to the symbols and indices used:
M is selected from the group consisting of Y, Gd, Lu and Tb or mixtures of two or more of these metals;
Hal is selected from the group consisting of F, Cl, Br and I or mixtures of two or more of these elements;
   0≦x≦0.3;
   0<y≦0.2;
   0≦z≦1.0;
   0≦w≦1.0.

The compounds according to the invention are obtained by the use of MnHal₂, in particular MnF₂, for the co-doping.

All Ce³⁺- and Mn²⁺-co-doped garnet phosphors described here have emission bands between 520 and 600 nm and a high photoluminescence quantum yield.

The compounds according to the invention can usually be excited in the blue spectral region, preferably at about 450 nm, and usually emit with an emission maximum in the green or yellow spectral region. The compounds according to the invention have a broad emission spectrum up to a region above 600 nm and thus also cover part of the red spectral region.

In the context of this application, blue light denotes light whose emission maximum is between 400 and 459 nm, cyan-coloured light denotes light whose emission maximum is between 460 and 505 nm, green light denotes light whose emission maximum is between 506 and 545 nm, yellow light denotes light whose emission maximum is between 546 and 565 nm, orange light denotes light whose emission maximum is between 566 and 600 nm and red light denotes light whose emission maximum is between 601 and 670 nm.

In a preferred embodiment of the invention, M is selected from the group Y, Lu or a mixture of Y and Lu. M particularly preferably stands for Lu. The compound preferably contains Al or a combination of Al with up to 20 atom-% of Ga.

In a further preferred embodiment of the invention, Hal is selected from the group consisting of F, Cl and Br, particularly preferably F and Cl and very particularly preferably F.

In still a further preferred embodiment of the invention, the following applies to the index x: 0.005≦x≦0.20, particularly preferably 0.010≦x≦0.15, very particularly preferably 0.015≦x≦0.10.

In still a further preferred embodiment of the invention, the following applies to the index y: 0.001≦y≦0.2, particularly preferably 0.003≦y≦0.1, very particularly preferably 0.005≦y≦0.05.

In still a further preferred embodiment of the invention, the following applies to the index z: 0≦z≦1, particularly preferably 0≦z≦0.5, very particularly preferably z=0.

In still a further preferred embodiment of the invention, the following applies to the index w: 0≦w≦1, particularly preferably 0≦w≦0.5, very particularly preferably w=0.

Particularly preferably, at least one of the two indices z and w is =0. Thus, if z is >0, w is preferably =0, and if w is >0, z is preferably =0.

In a particularly preferred embodiment of the invention, the above-mentioned preferences apply simultaneously. Particular preference is therefore given to compounds of the formula (1) for which:
M is selected from the group consisting of Y and Lu or mixtures of these metals;
Hal is selected from the group consisting of F and Cl or mixtures of these elements;
   0.005≦x≦0.20;
   0.001≦y≦0.2;
   0≦z≦0.5;
   0≦w≦0.5.

Very particular preference is given to compounds of the formula (1) for which:

M is selected from the group consisting of Y and Lu;

### Hal is F;

0.010≦x≦0.15, preferably 0.015≦x≦0.10;
0.003≦y≦0.1, preferably 0.005≦y≦0.05;
z=0;
w=0.

The present invention furthermore relates to a process for the preparation of a compound of the formula (1), comprising the steps:
a) preparation of a solution comprising M, Al, Mn, Hal and optionally Ce, Ga and/or Sc;
b) addition of citric acid or tartaric acid;
c) drying; and
d) calcination of the mixture at elevated temperature.

The various salts in step a) can either be added successively in any desired sequence or simultaneously. The citric or tartaric acid is added after the addition of all salts in step a). Preference is given to the use of citric acid.

The ion M here is preferably employed in the form of the corresponding oxide M₂O₃, and the solution of M is prepared by dissolution in an acid, in particular in nitric acid.

Furthermore, Mn and Hal are preferably employed in the form of a salt MnHal₂, in particular MnF₂. It is also possible to employ other water-soluble manganese salts, for example manganese acetate. In this case, the halogen Hal must be added separately, for example in the form of the ammonium salt (NH₄)Hal.

Suitable for Al are various salts, for example nitrate, acetate or other water-soluble Al salts. Preference is given to the nitrate salts.

Suitable for Ce, which is optionally present, are various salts, for example nitrate, oxalate or acetate. Preference is given to cerium nitrate.

If the compound according to the invention contains Ga and/or Sc, these elements are preferably employed in the form of their nitrates, acetates or oxalates.

The solution in step a) is preferably an acidic solution. M₂O₃ is preferably firstly dissolved in an acid, in particular in concentrated nitric acid. The other salts are added thereto as solid or as aqueous solution, in particular as solid.

The drying of the mixture is preferably carried out at elevated temperature, for example in a temperature range from 70-150° C., for example in a drying cabinet.

The calcination of the mixture in step d) of the process according to the invention is preferably carried out in two steps.

The first calcination step here is carried out in air or under oxidising conditions. Preference is given here to a reaction time of 0.5 to 10 h, particularly preferably 1 to 5 h, very particularly preferably 2 to 4 h, and a temperature in the range from 800 to 1300° C., particularly preferably from 900 to 1100° C., very particularly preferably from 950 to 1050° C.

In a preferred embodiment of the invention, the pre-calcined product from the first calcination step is cooled and comminuted, for example ground in a mortar, before it is subjected to the second calcination step.

The second calcination step is preferably carried out under reducing or at least under non-oxidising conditions. Preference is given here to a reaction time of 1 to 15 h, particularly preferably 2 to 10 h, very particularly preferably 3 to 5 h, and a temperature in the range from 1400 to 1800° C., particularly preferably between 1500 and 1700° C., very particularly preferably between 1550 and 1650° C.

The non-oxidising or reducing conditions are established here, for example, using inert gases or carbon monoxide, forming gas or hydrogen or vacuum or an oxygen-deficiency atmosphere. Preference is given to a CO atmosphere.

The calcination can be carried out, for example, by introducing the mixtures obtained into a high-temperature furnace, for example into a chamber furnace. A suitable reaction vessel is, for example, a corundum crucible with lid.

It is preferred for the compounds according to the invention to be comminuted, for example by grinding in a mortar, after the second calcination step.

In still a further embodiment, the compounds according to the invention can be coated. Suitable for this purpose are all coating methods as are known to the person skilled in the art from the prior art and are used for phosphors. Suitable materials for the coating are, in particular, metal oxides and nitrides, in particular alkaline-earth metal oxides, such as Al₂O₃, and alkaline-earth metal nitrides, such as AlN, as well as SiO₂. The coating can be carried out here, for example, by fluidised-bed methods or by wet-chemical methods. Suitable coating methods are disclosed, for example, in JP 04-304290, WO 91/10715, WO 99/27033, US 2007/0298250, WO 2009/065480 and WO 2010/075908. The aim of the coating can on the one hand be higher stability of the phosphors, for example to air or moisture. However, the aim may also be improved coupling in and out of light through a suitable choice of the surface of the coating and the refractive indices of the coating material.

The present invention again furthermore relates to the use of the compound according to the invention as phosphor or conversion phosphor, in particular for the partial or complete conversion of the blue or near-UV emission of a light-emitting diode into light having a longer wavelength.

The compounds according to the invention are therefore also called phosphors below.

The present invention therefore furthermore relates to an emission-converting material comprising a compound according to the invention. The emission-converting material may consist of the compound according to the invention and would in this case be equivalent to the term “conversion phosphor” defined above. It may also be preferred for the emission-converting material according to the invention also to comprise further conversion phosphors besides the compound according to the invention. In this case, the emission-converting material according to the invention preferably comprises a mixture of at least two conversion phosphors, where at least one thereof is a compound according to the invention. It is particularly preferred for the at least two conversion phosphors to be phosphors which emit light of wavelengths which are complementary to one another.

Compounds according to the invention give rise to good LED qualities even employed when in small amounts. The LED quality is described here via conventional parameters, such as, for example, the colour rendering index (CRI), the correlated colour temperature (CCT), lumen equivalent or absolute lumen, or the colour point in CIE x and y coordinates.

The colour rendering index (CRI) is a dimensionless lighting quantity, familiar to the person skilled in the art, which compares the colour reproduction faithfulness of an artificial light source with that of sunlight or filament light sources (the latter two have a CRI of 100).

The correlated colour temperature (CCT) is a lighting quantity, familiar to the person skilled in the art, with the unit kelvin. The higher the numerical value, the higher the blue content of the light and the colder the white light from an artificial radiation source appears to the observer. The CCT follows the concept of the black body radiator, whose colour temperature describes the so-called Planck curve in the CIE diagram.

The lumen equivalent is a lighting quantity, familiar to the person skilled in the art, with the unit lm/W which describes the magnitude of the photometric luminous flux in lumens of a light source at a certain radiometric radiation power with the unit watt. The higher the lumen equivalent, the more efficient a light source.

The lumen is a photometric lighting quantity, familiar to the person skilled in the art, which describes the luminous flux of a light source, which is a measure of the total visible radiation emitted by a radiation source. The greater the luminous flux, the brighter the light source appears to the observer.

CIE x and CIE y stand for the coordinates in the standard CIE colour chart (here standard observer 1931), familiar to the person skilled in the art, by means of which the colour of a light source is described.

All the quantities mentioned above can be calculated from the emission spectra of the light source by methods familiar to the person skilled in the art.

The excitability of the phosphors according to the invention extends over a broad range, which extends from about 410 nm to 530 nm, preferably 430 nm to about 500 nm. The maximum of the excitation curve is usually at about 450 nm.

The present invention furthermore relates to a light source which comprises at least one primary light source and at least one compound according to the invention. The emission maximum of the primary light source here is usually in the range 410 nm to 530 nm, preferably 430 nm to about 500 nm. A range between 440 and 480 nm is especially preferred, where the primary radiation is converted partly or fully into longer-wave radiation by the phosphor according to the invention.

In a preferred embodiment of the light source according to the invention, the primary light source is a luminescent indium aluminium gallium nitride, in particular of the formula InᵢGaⱼAlₖN, where 0≦i, 0≦j, 0≦k, and i+j+k=1.

Possible forms of light sources of this type are known to the person skilled in the art. These can be light-emitting LED chips of various structure.

In a further preferred embodiment of the light source according to the invention, the primary light source is a luminescent arrangement based on ZnO, TCO (transparent conducting oxide), ZnSe or SiC or an arrangement based on an organic light-emitting layer (OLED).

In a further preferred embodiment of the light source according to the invention, the primary light source is a source which exhibits electroluminescence and/or photoluminescence. The primary light source may furthermore also be a plasma or discharge source.

Corresponding light sources according to the invention are also known as light-emitting diodes or LEDs.

The phosphors according to the invention can be employed individually or as a mixture with the following phosphors, which are familiar to the person skilled in the art. Corresponding phosphors which are in principle suitable for mixtures are, for example:

Ba₂SiO₄:Eu²⁺, BaSi₂O₅:Pb²⁺, BaₓSr₁₋ₓF₂:Eu²⁺, BaSrMgSi₂O₇:Eu²⁺, BaTiP₂O₇, (Ba,Ti)₂P₂O₇:Ti, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺,Mn²⁺, CaAl₂O₄:Tb³⁺, Ca₃Al₂Si₃O₁₂:Ce³⁺, Ca₃Al₂Si₃O₁₂:Ce³⁺, Ca₃Al₂Si₃O,₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₆:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺, Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, Cal₂:Eu²⁺ in SiO₂, Cal₂:Eu²⁺, Mn²⁺ in SiO₂, CaLaBO₄:Eu³⁺, CaLaB₃O₇:Ce³⁺, Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺, Mn²⁺, Ca₂MgSi₂O₇:Eu²⁺, Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺, Mn²⁺, Ca₅(PO₄)₃F:Mn²⁺, Ca₅(PO₄)₃F:Sb³⁺, Ca₅(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺, Mn²⁺, CaSO₄:Pb²⁺, CaS:Pb²⁺, CaS:Pb²⁺,Cl, CaS:Pb²⁺, Mn²⁺, CaS:Pr³⁺,Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺, Pb, CaSiO₃:Pb²⁺, CaSiO₃:Pb²⁺, Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺,Cr, CdS:In, CdS:In, CdS:In,Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂Pr³⁺, Gd₂O₂S:Pr,Ce,F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46(70%)+P47 (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}: Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺,Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺, Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇Sn²⁺, β-Sr₃(PO₄)₂:Sn²⁺, β-Sr₃(PO₄)₂:Sn²⁺,Mn²⁺(Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃Pr³⁺, SrTiO₃Pr³⁺, Al³⁺, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺, Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu, Pr), Y₂O₃:Bi³⁺, YOBr:Eu³⁺, Y₂O₃:Ce, Y₂O₃:Er³⁺, Y₂O₃:Eu³⁺, Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺, Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺, Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS—CdS:Ag⁺,Cl, ZnS—CdS:Cu,Br, ZnS—CdS:Cu, I, ZnS:Cl⁻, ZnS:Eu²⁺, ZnS:Cu, ZnS:Cu⁺, Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:P³⁻, Cl⁻, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺, P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺, Cl and ZnWO₄.

The compound according to the invention exhibits, in particular, advantages when mixed with further phosphors of another fluorescence colour or on use in LEDs together with phosphors of this type. The compounds according to the invention are preferably employed together with red-emitting phosphors. It has been found that, in particular on combination of the compounds according to the invention with red-emitting phosphors, optimisation of lighting parameters for white LEDs succeeds particularly well.

Corresponding red-emitting phosphors are known to the person skilled in the art or can be selected by the person skilled in the art from the list given above. Particularly suitable red-emitting phosphors here are nitrides, oxynitrides, sialons or sulfides. Examples are: CaAlSiN₃:Eu, 2-5-8-nitrides, such as (Ca,Sr,Ba)₂Si₅N₈:Eu, (Ca,Sr)AlSiN₃:Eu, (Ca,Sr)S:Eu, (Ca,Sr)(S,Se):Eu, (Sr,Ba,Ca)Ga₂S₄:Eu, and also europium-doped, oxy-nitridic compounds. Further examples of suitable red-emitting compounds are MgAl₂O₄:Mn⁴⁺ or Mg₈Ge₂O₁₁F₂:Mn⁴⁺. In a variant, the red-emitting oxynitrides are those of the formula

(EA)_{2-0.5y-x+1.5z}EuₓSi₅N_{8-y+z}O_{y}.n SiO₂

where EA stands for one or more elements selected from Ca, Sr and Ba, x stands for a value from the range from 0.005 to 1, y stands for a value from the range from 0.01 to 3, z stands for a value from the range from 0 to 3 and n stands for a value from the range from 0 to 5, preferably 0 to 2. The preparation and use of corresponding compounds are described in WO 2011/091839.

In a further preferred embodiment of the invention, red-emitting compounds of the formula

(EA)_{2-c+1.5z}Eu_{c}Si₅N_{8-2/3x+z}Oₓ.n SiO₂

are employed, where the indices used have the following meanings: EA stands for one or more elements selected from Ca, Sr, Ba; 0.01≦c≦0.2; 0<x≦1; 0≦z≦3.0 and a+b+c≦2+1.5z; and n stands for a value in the range from 0 to 5, preferably 0 to 2.

In a further preferred embodiment of the invention, it is preferred to use the compound according to the invention as the sole phosphor. The compound according to the invention also exhibits very good results on use as the sole phosphor due to the broad emission spectrum with a high red content.

In still a further embodiment of the invention, it is preferred for the phosphors to be arranged on the primary light source in such a way that the red-emitting phosphor is essentially hit by light from the primary light source, while the green-emitting phosphor is essentially hit by light which has already passed through the red-emitting phosphor or has been scattered thereby. This can be achieved by installing the red-emitting phosphor between the primary light source and the green-emitting phosphor.

The phosphors or phosphor combinations according to the invention can either be dispersed in a resin (for example epoxy or silicone resin) or, in the case of suitable size ratios, arranged directly on the primary light source or alternatively arranged remote therefrom, depending on the application (the latter arrangement also includes “remote phosphor technology”). The advantages of remote phosphor technology are known to the person skilled in the art and are revealed, for example, by the following publication: Japanese J. of Appl. Phys. Vol. 44, No. 21 (2005). L649-L651.

In a further embodiment, it is preferred for the optical coupling between the phosphor and the primary light source to be achieved by a light-conducting arrangement. This makes it possible for the primary light source to be installed at a central location and to be optically coupled to the phosphor by means of light-conducting devices, such as, for example, optical fibres. In this way, it is possible to achieve lamps adapted to the lighting wishes which merely consist of one or more different phosphors, which can be arranged to form a light screen, and an optical waveguide, which is coupled to the primary light source. In this way, it is possible to place a strong primary light source at a location which is favourable for electrical installation and to install lamps comprising phosphors which are coupled to the optical waveguides at any desired locations without further electrical cabling, but instead only by laying optical waveguides.

The invention furthermore relates to a lighting unit, in particular for the backlighting of display devices, characterised in that it comprises at least one light source according to the invention, and to a display device, in particular liquid-crystal display device (LC display), with backlighting, characterised in that it comprises at least one lighting unit according to the invention.

The particle size of the phosphors according to the invention for use in LEDs is usually between 50 nm and 30 μm, preferably between 1 μm and 20 μm.

For use in LEDs, the phosphors can also be converted into any desired outer shapes, such as spherical particles, platelets and structured materials and ceramics. These shapes are in accordance with the invention summarised under the term “shaped bodies”. The shaped body is preferably a “phosphor body”. The present invention thus furthermore relates to a shaped body comprising the phosphors according to the invention. The production and use of corresponding shaped bodies are familiar to the person skilled in the art from numerous publications.

Since Mn²⁺ is only employed in low concentrations (<1%) in the garnets described here, it is also advantageous to use the phosphors according to the invention in the form of translucent ceramics, since the optical path length, i.e. the thickness of the ceramic layer, in ceramic luminescence conversion screens can be increased owing to the reduced scattering compared with a powder layer. The present invention therefore furthermore relates to a ceramic comprising at least one compound according to the invention. The ceramic may then consist only of the compound according to the invention. However, it may also comprise matrix materials and/or further phosphors. Suitable matrix materials are, for example, undoped garnets, silicon dioxide (SiO₂), yttrium oxide (Y₂O₃) or aluminium oxide (Al₂O₃).

The compounds according to the invention have the following advantageous properties:
1) The compounds according to the invention have a high photoluminescence quantum efficiency.
2) The compounds according to the invention have only low thermal quenching. Thus, the TQ_{1/2} values of the compounds according to the invention are usually in the region above 500 K.
3) The high temperature stability of the compounds according to the invention also enables the material to be used in light sources with high thermal loads.

All variants of the invention described here can be combined with one another so long as the respective embodiments are not mutually exclusive. In particular, it is an obvious operation, on the basis of the teaching of this specification, as part of routine optimisation, precisely to combine various variants described here in order to obtain a specific particularly preferred embodiment. The following examples are intended to illustrate the present invention and show, in particular, the result of such illustrative combinations of the invention variants described. However, they should in no way be regarded as limiting, but instead are intended to stimulate generalisation. All compounds or components which are used in the preparations are either known and commercially available or can be synthesised by known methods. The temperatures indicated in the examples are always in ° C. It furthermore goes without saying that, both in the description and also in the examples, the amounts of the components added in the compositions always add up to a total of 100%. Percent data should always be regarded in the given connection.

### EXAMPLES

### Measurement Methods

The phase formation of the samples was checked by means of X-ray diffractometry. For this purpose, the Rigaku Miniflex II X-ray diffractometer with Bragg-Brentano geometry was used. The radiation source used was an X-ray tube with Cu-Kα radiation (λ=0.15418 nm). The tube was operated with a current strength of 15 mA and a voltage of 30 kV. The measurement was carried out in an angle range of 10-80° at 10°.min⁻¹.

The emission spectra were recorded using an Edinburgh Instruments Ltd. fluorescence spectrometer fitted with mirror optics for powder samples, at an excitation wavelength of 450 nm. The excitation source used was a 450 W Xe lamp.

Reflection spectra were determined using an Edinburgh Instruments Ltd. fluorescence spectrometer. For this purpose, the samples were placed and measured in a BaSO₄-coated Ulbricht sphere. Reflection spectra were recorded in a range from 250-800 nm. The white standard used was BaSO₄ (Alfa Aesar 99.998%). A 450 W Xe lamp was used as excitation source.

The excitation spectra were recorded using an Edinburgh Instruments Ltd. fluorescence spectrometer fitted with mirror optics for powder samples, at 550 nm. The excitation source used was a 450 W Xe lamp.

### Example 1

### Preparation of Lu₃₋ₓAl_{5-y}O_{12-y}:Ce³⁺(0.5%)Mn²⁺(0.1%)F⁻(0.1%) (corresponds to: Lu_{2.985}Ce_{0.015}Al_{4.995}Mn_{0.005}O_{11.995}F_{0.005})

3.6957 g of Lu₂O₃ (0.00929 mol) are dissolved in 15 ml of nitric acid with warming. 11.6548 g of Al(NO₃)₃ (0.03109 mol), 0.00289 g of MnF₂ (0.00003 mol), 0.04029 g of Ce(NO₃)₃ (0.00009 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then heated at 1700° C. under a CO atmosphere for 4 h and re-ground in a mortar. Thermal quenching TQ_{1/2}>500 K.

### Example 2

### Preparation of Lu₃₋ₓAl_{5-y}O_{12-y}:Ce³⁺(1.0%)Mn²⁺(0.1%)F⁻(0.1%) (corresponds to: Lu_{2.97}Ce_{0.03}Al_{4.995}Mn_{0.005}O_{11.995}F_{0.005})

3.6795 g of Lu₂O₃ (0.00925 mol) are dissolved in 15 ml of nitric acid with warming. 11.6549 g of Al(NO₃)₃ (0.03109 mol), 0.00289 g of MnF₂ (0.00003 mol), 0.08069 g of Ce(NO₃)₃ (0.00019 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. The compound has a photoluminescence quantum yield of 94%. Thermal quenching TQ_{1/2}>500 K.

### Example 3

### Preparation of Lu₃₋ₓAl_{5-y}O_{12-y}:Ce³⁺(1.5%)Mn²⁺(0.1%)F⁻(0.1%) (corresponds to: Lu_{2.955}Ce_{0.045}Al_{4.995}Mn_{0.005}O_{11.995}F_{0.005})

3.6633 g of Lu₂O₃ (0.00921 mol) are dissolved in 15 ml of nitric acid with warming. 11.6735 g of Al(NO₃)₃ (0.03109 mol), 0.00289 g of MnF₂ (0.00003 mol), 0.1212 g of Ce(NO₃)₃ (0.00028 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1600° C. under a CO atmosphere for 4 h and re-ground in a mortar.

### Example 4

### Preparation of Lu₃₋ₓAl_{5-y}O_{12-y}:Ce³⁺(2.0%)Mn²⁺(0.1%)F⁻(0.1%) (corresponds to: Lu_{2.940}Ce_{0.060}Al_{4.995}Mn_{0.005}O_{11.995}F_{0.005})

3.6471 g of Lu₂O₃ (0.00917 mol) are dissolved in 15 ml of nitric acid with warming. 11.6829 g of Al(NO₃)₃ (0.0311 mol), 0.0029 g of MnF₂ (0.00003 mol), 0.1617 g of Ce(NO₃)₃ (0.00037 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 5

### Preparation of Lu₃₋ₓAl_{5-y}O_{12-y}:Ce³⁺(2.5%)Mn²⁺(0.1%)F⁻(0.1%) (corresponds to: Lu_{2.925}Ce_{0.075}Al_{4.995}Mn_{0.005}O_{11.995}F_{0.005})

3.6308 g of Lu₂O₃ (0.00912 mol) are dissolved in 15 ml of nitric acid with warming. 11.6923 g of Al(NO₃)₃ (0.0312 mol), 0.0029 g of MnF₂ (0.00003 mol), 0.2023 g of Ce(NO₃)₃ (0.00047 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 6

### Preparation of Lu₃₋ₓAl_{5-y}O_{12-y}:Ce³⁺(0.5%)Mn²⁺(0.5%)F⁻(0.5%) (corresponds to: Lu_{2.985}Ce_{0.015}Al_{4.975}Mn_{0.025}O_{11.975}F_{0.025})

3.6908 g of Lu₂O₃ (0.00928 mol) are dissolved in 15 ml of nitric acid with warming. 11.6007 g of Al(NO₃)₃ (0.0309 mol), 0.01444 g of MnF₂ (0.00016 mol), 0.04029 g of Ce(NO₃)₃ (0.00009 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 7

### Preparation of Lu₃₋ₓAl_{5-y}O_{12-y}:Ce³⁺(1.0%)Mn²⁺(0.5%)F⁻(0.5%) (corresponds to: Lu_{2.970}Ce_{0.030}Al_{4.975}Mn_{0.025}O_{11.975}F_{0.025})

3.6754 g of Lu₂O₃ (0.00924 mol) are dissolved in 15 ml of nitric acid with warming. 11.6082 g of Al(NO₃)₃ (0.0309 mol), 0.01445 g of MnF₂ (0.00016 mol), 0.08069 g of Ce(NO₃)₃ (0.00019 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. The compound has a photoluminescence quantum yield of 71%. Thermal quenching TQ_{1/2}>500 K.

### Example 8

### Preparation of Lu₃₋ₓAl_{5-y}O_{12-y}:Ce³⁺(1.5%)Mn²⁺(0.5%)F⁻(0.5%) (corresponds to: Lu_{2.955}Ce_{0.045}Al_{4.975}Mn_{0.025}O_{11.975}F_{0.025})

3.6595 g of Lu₂O₃ (0.00919 mol) are dissolved in 15 ml of nitric acid with warming. 11.6156 g of Al(NO₃)₃ (0.03096 mol), 0.01445 g of MnF₂ (0.00016 mol), 0.12106 g of Ce(NO₃)₃ (0.00028 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 9

### Preparation of Lu₃₋ₓAl_{5-y}O_{12-y}:Ce³⁺(2.0%)Mn²⁺(0.5%)F⁻(0.5%) (corresponds to: Lu_{2.940}Ce_{0.060}Al_{4.975}Mn_{0.025}O_{11.975}F_{0.025})

3.64329 g of Lu₂O₃ (0.00916 mol) are dissolved in 15 ml of nitric acid with warming. 11.6475 g of Al(NO₃)₃ (0.03105 mol), 0.01447 g of MnF₂ (0.00016 mol), 0.16151 g of Ce(NO₃)₃ (0.00037 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 10

### Preparation of Lu₃₋ₓAl_{5-y}O_{12-y}:Ce³⁺(2.5%)Mn²⁺(0.5%)F⁻(0.5%) (corresponds to: Lu_{2.925}Ce_{0.075}Al_{4.975} Mn_{0.025}O_{11.975}F_{0.025})

3.6270 g of Lu₂O₃ (0.00912 mol) are dissolved in 15 ml of nitric acid with warming. 11.6268 g of Al(NO₃)₃ (0.03099 mol), 0.01447 g of MnF₂ (0.00016 mol), 0.20195 g of Ce(NO₃)₃ (0.00047 mol) and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then calcined at 1700° C. under a CO atmosphere for 4 h and re-ground in a mortar. Thermal quenching TQ_{1/2}>500 K.

### Example 11

### Preparation of Lu_{2.37}Gd_{0.6}Ce_{0.03}Mn_{0.005}Al_{3.995}GaO_{11.995}F_{0.005}

2.6701 g of Lu₂O₃ are dissolved in 15 ml of nitric acid with warming. 8.486 g of Al(NO₃)₃, 0.6158 g of Gd₂O₃, 0.0027 g of MnF₂, 0.5307 g of Ga₂O₃, 0.0738 g of Ce(NO₃)₃ and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then heated at 1600° C. under a CO atmosphere for 4 h and re-ground in a mortar.

### Example 12

### Preparation of Lu_{2.37}Y_{0.6}Ce_{0.03}Mn_{0.005}Al_{3.995}ScO_{11.995}F_{0.005}

2.885 g of Lu₂O₃ are dissolved in 15 ml of nitric acid with warming. 9.1689 g of Al(NO₃)₃, 0.0028 g of MnF₂, 0.4145 g of Y₂O₃, 0.4219 g of Sc₂O₃, 0.0797 g of Ce(NO₃)₃ and 15 g of citric acid are subsequently added little by little with water. The solution is evaporated overnight in a drying cabinet at 130° C., and the citrate precursor formed is ground in a mortar. The powder is pre-calcined under air at 1000° C. for 3 h and subsequently ground in a mortar. The product is then heated at 1600° C. under a CO atmosphere for 4 h and re-ground in a mortar.

### Example 13

### General Example of the LED Application of the Phosphors

General procedure for the construction and measurement of pc-LEDs: A mass of m_{LS} (in g) of the phosphor indicated in the respective LED example is weighed out, m_{silicone} (in g) of an optically transparent silicone is added, and the components are subsequently mixed homogeneously in a planetary centrifugal mixer, so that the phosphor concentration in the total mass is c_{LS} (in wt. %). The silicone/phosphor mixture obtained in this way is applied to the chip of a blue semiconductor LED with the aid of an automatic dispenser and cured with supply of heat. The blue semiconductor LEDs used in the present examples for the LED characterisation have an emission wavelength of 442 nm and are operated with a current strength of 350 mA. The photometric characterisation of the LED is carried out using an Instrument Systems CAS 140 spectrometer and an ISP 250 integration sphere connected thereto. The LED is characterised by determination of the wavelength-dependent spectral power density. The resultant spectrum of the light emitted by the LED is used to calculate the colour point coordinates CIE x and y and the luminous flux Φᵥ (in Im).

### Example 14

### Production of a pc-LED Using the Phosphor in Accordance with Example 1

| m_{LS}: | 1.3 | g |
|---|---|---|
| m_{silicone}: | 8.7 | g |
| c_{LS}: | 13 | wt. % |
| CIE (1931) x: | 0.269 | |
| CIE (1931) y: | 0.358 | |
| Φᵥ: | 57 | lm |

### Example 15

### Production of a pc-LED Using the Phosphor in Accordance with Example 3

| m_{LS}: | 1.2 | g |
|---|---|---|
| m_{silicone}: | 8.8 | g |
| c_{LS}: | 12 | wt. % |
| CIE (1931) x: | 0.284 | |
| CIE (1931) y: | 0.354 | |
| Φᵥ: | 56 | lm |

### Example 16

### Production of a pc-LED Using the Phosphor in Accordance with Example 6

| m_{LS}: | 1.5 | g |
|---|---|---|
| m_{silicone}: | 8.5 | g |
| c_{LS}: | 15 | wt. % |
| CIE (1931) x: | 0.238 | |
| CIE (1931) y: | 0.394 | |
| Φᵥ: | 63 | lm |

### Example 17

### Production of a pc-LED Using the Phosphor in Accordance with Example 8

| m_{LS}: | 1.5 | g |
|---|---|---|
| m_{silicone}: | 8.5 | g |
| c_{LS}: | 15 | wt. % |
| CIE (1931) x: | 0.275 | |
| CIE (1931) y: | 0.383 | |
| Φᵥ: | 65 | lm |

### DESCRIPTION OF THE FIGURES

FIG. 1: X-ray powder diffraction pattern of Lu₃₋ₓAl_{5-y}O_{12-z}: Ce³⁺ (0.5%) Mn²⁺ (0.1%) F⁻ (0.1%) (Example 1) (top) with the reference diffraction pattern of cubic Lu garnet (12005-21-9) (bottom).

FIG. 2: emission spectrum of Lu₃₋ₓAl_{5-y}O_{12-z}: Ce³⁺ (0.5%) Mn²⁺ (0.1%) F⁻ (0.1%) (Example 1).

FIG. 3: reflection spectrum of Lu₃₋ₓAl_{5-y}O_{12-z}: Ce³⁺ (0.5%) Mn²⁺ (0.1%) F⁻ (0.1%) (Example 1).

FIG. 4: excitation spectrum of Lu₃₋ₓAl_{5-y}O_{12-z}: Ce³⁺ (0.5%) Mn²⁺ (0.1%) F⁻ (0.1%) (Example 1).

FIG. 5: emission spectrum of Lu₃₋ₓAl_{5-y}O_{12-z}: Ce³⁺ (1.0%) Mn²⁺ (0.1%) F⁻ (0.1%) (Example 2).

FIG. 6: emission spectrum of Lu₃₋ₓAl_{5-y}O_{12-z}: Ce³⁺ (1.5%) Mn²⁺ (0.1%) F⁻ (0.1%) (Example 3).

FIG. 7: emission spectrum of Lu₃₋ₓAl_{5-y}O_{12-z}: Ce³⁺ (2.0%) Mn²⁺ (0.1%) F⁻ (0.1%) (Example 4).

FIG. 8: emission spectrum of Lu₃₋ₓAl_{5-y}O_{12-z}: Ce³⁺ (2.5%) Mn²⁺ (0.1%) F⁻ (0.1%) (Example 5).

FIG. 9: emission spectrum of Lu₃₋ₓAl_{5-y}O_{12-z}: Ce³⁺ (0.5%) Mn²⁺ (0.5%) F⁻ (0.5%) (Example 6).

FIG. 10: emission spectrum of Lu₃₋ₓAl_{5-y}O_{12-z}: Ce³⁺ (1.0%) Mn²⁺ (0.5%) F⁻ (0.5%) (Example 7).

FIG. 11: emission spectrum of Lu₃₋ₓAl_{5-y}O_{12-z}: Ce³⁺ (1.5%) Mn²⁺ (0.5%) F⁻ (0.5%) (Example 8).

FIG. 12: emission spectrum of Lu₃₋ₓAl_{5-y}O_{12-z}: Ce³⁺ (2.0%) Mn²⁺ (0.5%) F⁻ (0.5%) (Example 9).

FIG. 13: emission spectrum of Lu₃₋ₓAl_{5-y}O_{12-z}: Ce³⁺ (2.5%) Mn²⁺ (0.5%) F⁻ (0.5%) (Example 10).

FIG. 14: X-ray powder diffraction pattern of Lu_{2.37}Gd_{0.6}Ce_{0.03}Mn_{0.005}Al_{3.995}GaO_{11.99}F_{0.005} (Example 11) (top) with the reference diffraction pattern of cubic Lu garnet (12005-21-9) (bottom).

FIG. 15: emission spectrum of Lu_{2.37}Gd_{0.6}Ce_{0.03}Mn_{0.005}Al_{3.995}GaO_{11.995}F_{0.005} (Example 11).

FIG. 16: X-ray powder diffraction pattern of Lu_{2.37}Y_{0.6}Ce_{0.03}Mn_{0.005}Al_{3.995}ScO_{11.99}F_{0.005} (Example 12) (top) with the reference diffraction pattern of cubic Lu garnet (12005-21-9) (bottom).

FIG. 17: emission spectrum of Lu_{2.37}Y_{0.6}Ce_{0.03}Mn_{0.005}Al_{3.995}ScO_{11.995}F_{0.005} (Example 12).

FIG. 18: LED spectrum of a phosphor-converted LED from Example 14, which comprises the material from Example 1.

FIG. 19: LED spectrum of a phosphor-converted LED from Example 15, which comprises the material from Example 3.

FIG. 20: LED spectrum of a phosphor-converted LED from Example 16, which comprises the material from Example 6.

FIG. 21: LED spectrum of a phosphor-converted LED from Example 17, which comprises the material from Example 8.

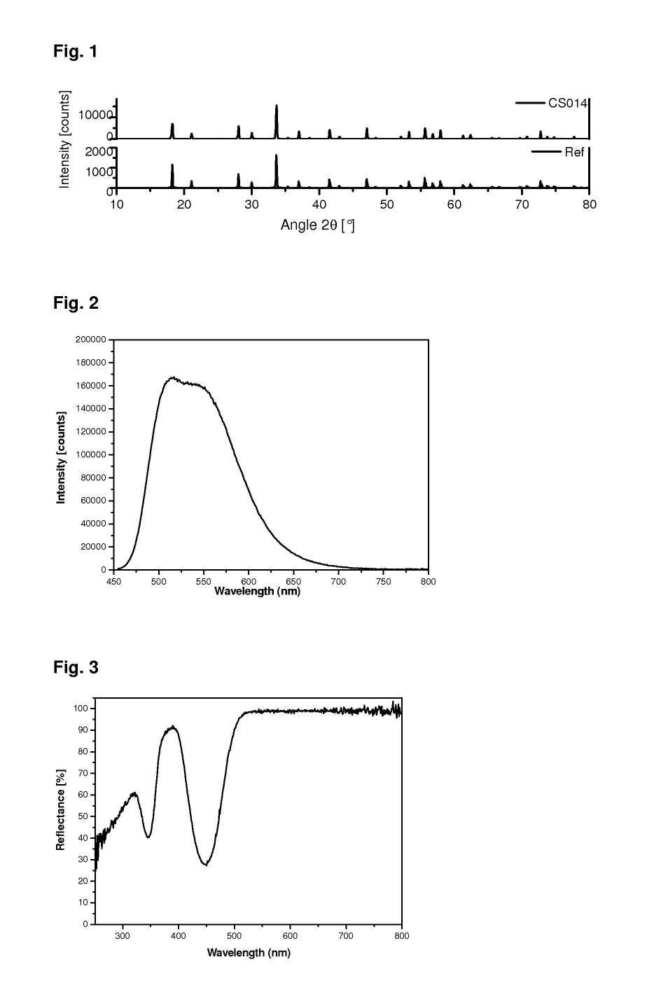

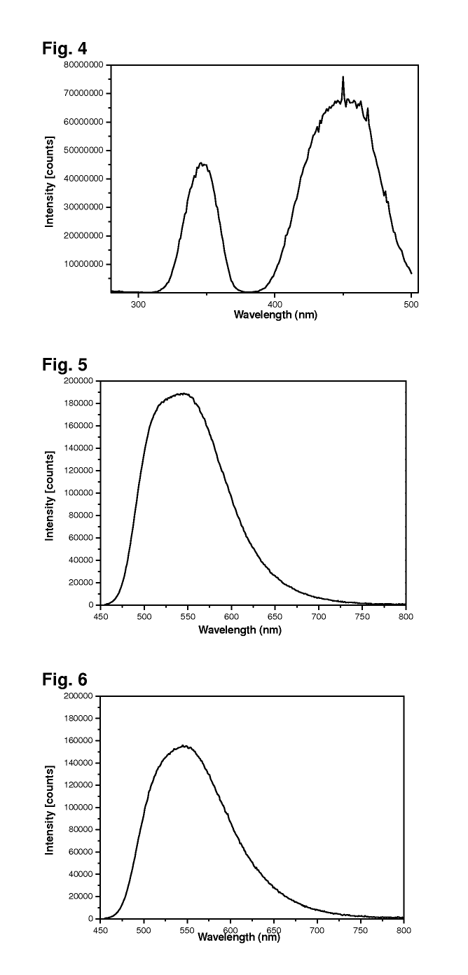

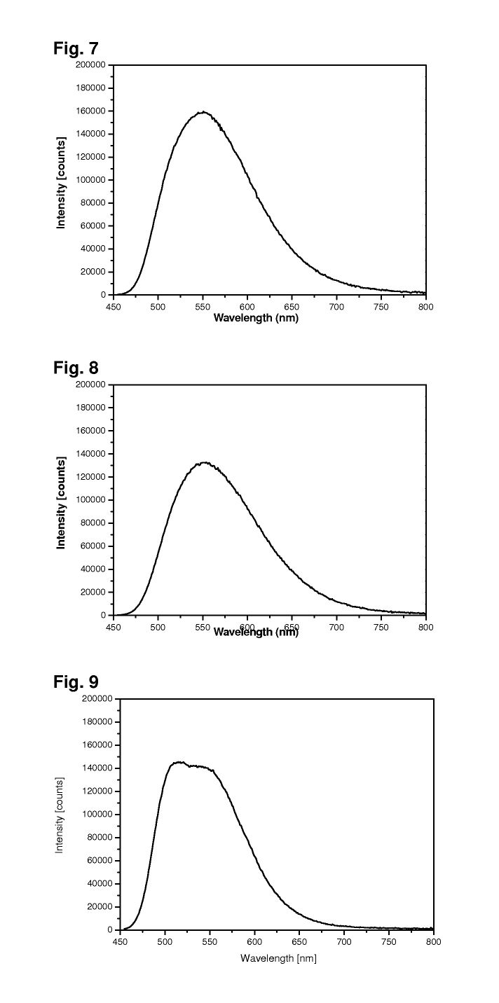

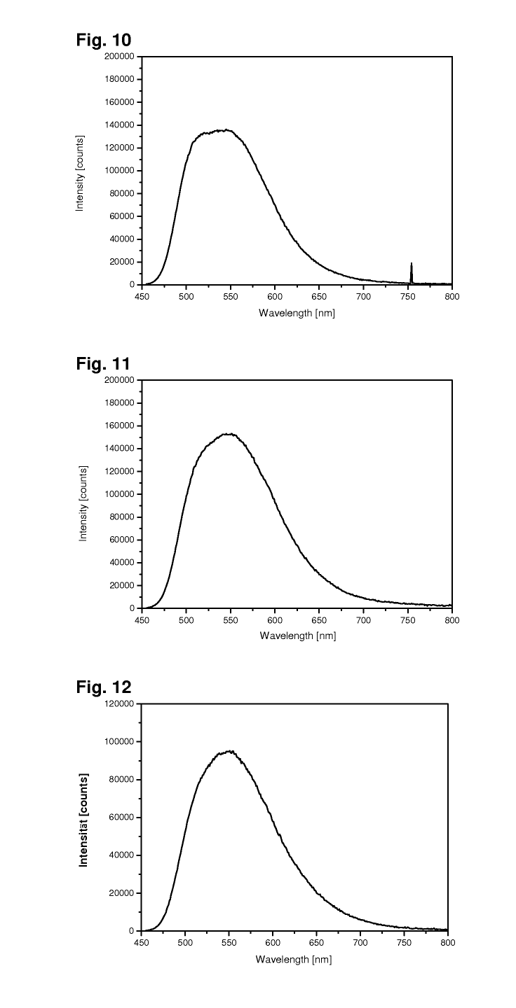

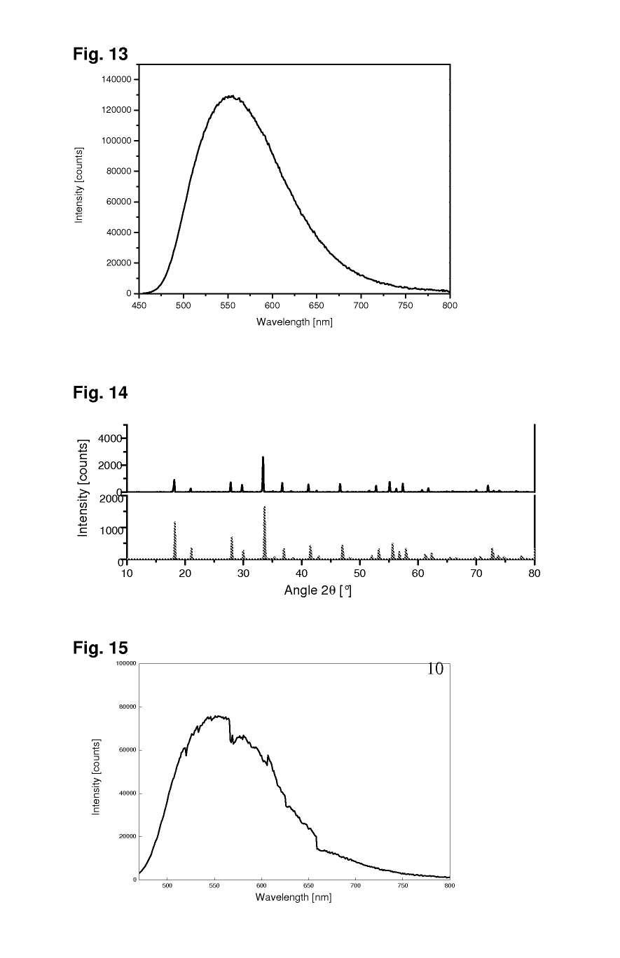

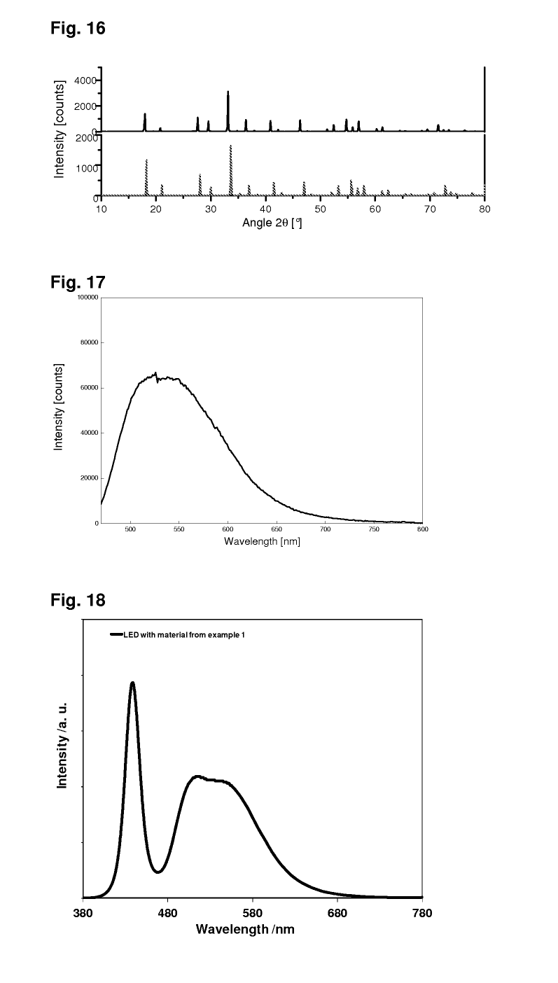

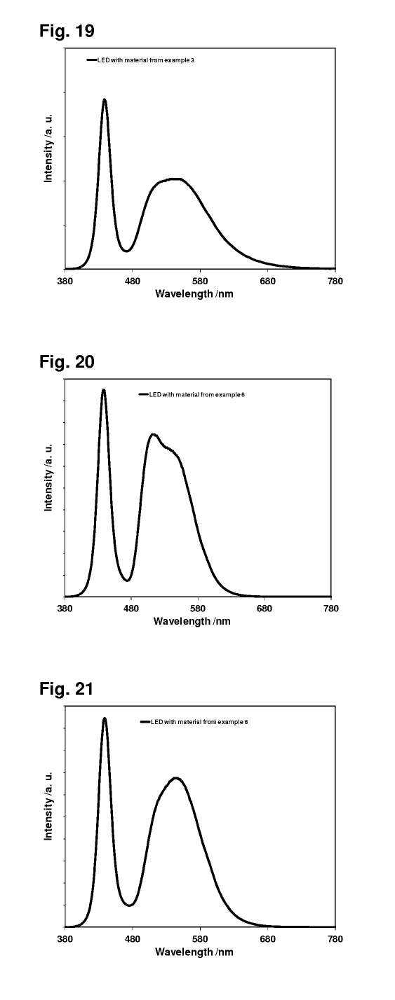

1. Compound of the formula (1),
M₃₋ₓCeₓ(Al_{5-y-z-w}Ga_{z}Sc_{w})Mn_{y}O_{12-y}Hal_{y} (1)
where the following applies to the symbols and indices used:
M is selected from the group consisting of Y, Gd, Lu and Tb or mixtures of two or more of these metals;
Hal is selected from the group consisting of F, Cl, Br and I or mixtures of two or more of these elements;
0≦x≦0.3;
0<y≦0.2;
0≦z≦1.0;
0≦w≦1.0.

2. Compound according to claim 1, characterised in that M is selected from the group Y, Lu or a mixture of Y and Lu.

3. Compound according to claim 1, characterised in that Hal is selected from the group consisting of F and Cl.

4. Compound according to claim 1, characterised in that the following applies: 0.005≦x≦0.20.

5. Compound according to claim 1, characterised in that the following applies: 0.001≦y≦0.2.

6. Compound according to claim 1, characterised in that the following applies: 0≦z≦0.5 and 0≦w≦0.5, where at least one of the indices z and/or w is =0.

7. Compound according to claim 1, characterised in that the following applies to the symbols and indices used:
M is selected from the group consisting of Y and Lu or mixtures of these metals;
Hal is selected from the group consisting of F and Cl or mixtures of these elements;
0.005≦x≦0.20;
0.001≦y≦0.2;
0≦z≦0.5;
0≦w≦0.5,
where at least one of the indices z and/or w is =0.

8. Compound according to claim 1, characterised in that the compound is coated on the surface with another compound.

9. Process for the preparation of a compound according to claim 1, comprising the steps:
a) preparation of a solution comprising M, Al, Mn, Hal and optionally Ce, Ga and/or Sc;
b) addition of citric acid or tartaric acid;
c) drying; and
d) calcination of the mixture at elevated temperature.

10. A phosphor or conversion phosphor for the partial or complete conversion of blue or near-UV emission into light having a longer wavelength, which comprises a compound of claim 1.

11. Emission-converting material comprising a compound according to claim 1 and optionally one or more further conversion phosphors.

12. Light source comprising at least one primary light source and at least one compound according to claim 1.

13. Lighting unit comprising at least one light source according to claim 12.

14. Ceramic comprising at least one compound according to claim 1 and optionally one or more matrix materials.

15. Light source comprising at least one primary light source and at least one emission-converting material according to claim 11.

16. Ceramic comprising at least one emission-converting material according to claim 11 and optionally one or more matrix materials.
